(19) United States
(12) Patent Application Publication
(10) Pub. No.: US 2024/0014799 A1
(43) Pub. Date: Jan. 11, 2024

(54) ACOUSTIC WAVE DEVICE

(71) Applicant: Murata Manufacturing Co., Ltd., Nagaokakyo-shi (JP)

(72) Inventors: Takeshi NAKAO, Nagaokakyo-shi (JP); Seiji KAI, Nagaokakyo-shi (JP); Hisashi YAMAZAKI, Nagaokakyo-shi (JP)

(21) Appl. No.: 18/369,895

(22) Filed: Sep. 19, 2023

Related U.S. Application Data
(63) Continuation of application No. PCT/JP2022/016146, filed on Mar. 30, 2022.
(60) Provisional application No. 63/195,801, filed on Jun. 2, 2021.
(60) Provisional application No. 63/168,321, filed on Mar. 31, 2021.

(51) Int. Cl. H03H 9/13; H03H 9/02; H03H 9/205; H03H 9/60

(52) U.S. Cl. CPC H03H 9/132; H03H 9/02015; H03H 9/02157; H03H 9/133; H03H 9/205; H03H 9/605

(57) ABSTRACT

An acoustic wave device includes a piezoelectric substrate including a support including a support substrate and a piezoelectric layer on the support and including first and second main surfaces, a functional electrode on the first or second main surface and including a pair of electrodes, a first support on the piezoelectric substrate and surrounding the functional electrode, at least one second support on the piezoelectric substrate in a portion surrounded by the first support, and a lid on the first and second supports. The second support does not overlap an intersecting region when viewed from an electrode extending direction and from an electrode facing direction.

### CROSS REFERENCE TO RELATED APPLICATIONS

This application claims the benefit of priority to Provisional Patent Application No. 63/168,321 filed on Mar. 31, 2021 and Provisional Patent Application No. 63/195,801 filed on Jun. 2, 2021, and is a Continuation application of PCT Application No. PCT/JP2022/016146 filed on Mar. 30, 2022. The entire contents of each application are hereby incorporated herein by reference.

### BACKGROUND OF THE INVENTION

### 1. Field of the Invention

The present invention relates to an acoustic wave device.

### 2. Description of the Related Art

Acoustic wave devices have been widely used in filters of mobile phones and the like. For example, Japanese Unexamined Patent Application Publication No. 2012-257019 discloses an acoustic wave device using Lamb waves as plate waves. In this acoustic wave device, a piezoelectric substrate is provided on a support. The piezoelectric substrate is made of LiNbO₃ or LiTaO₃. An interdigital transducer (IDT) electrode is provided on the upper surface of the piezoelectric substrate. A voltage is applied between a plurality of electrode fingers connected to one potential of the IDT electrode and a plurality of electrode fingers connected to the other potential. As a result, Lamb waves are excited. Reflectors are provided on both sides of the IDT electrode. As such, an acoustic wave resonator using Lamb waves is formed.

In the acoustic wave device described in Japanese Unexamined Patent Application Publication No. 2012-257019, an unnecessary wave propagating on the surface of the piezoelectric substrate may be generated. The electrical characteristics of the acoustic wave device may deteriorate due to the influence of the unnecessary wave.

### SUMMARY OF THE INVENTION

Preferred embodiments of the present invention provide acoustic wave devices that each reduce or prevent deterioration of electrical characteristics caused by an unnecessary wave.

An acoustic wave device according to a preferred embodiment of the present invention includes a piezoelectric substrate including a support including a support substrate and a piezoelectric layer on the support and including a first main surface and a second main surface facing each other, at least one functional electrode on the first main surface or the second main surface of the piezoelectric layer and including at least one pair of electrodes, a first support on the piezoelectric substrate and surrounding the functional electrode, at least one second support on the piezoelectric substrate and located in a portion surrounded by the first support, and a lid portion on the first support and the second support, wherein a direction in which the adjacent electrodes face each other is an electrode facing direction, a region in which the adjacent electrodes overlap each other when viewed from the electrode facing direction is an intersecting region, and a direction in which the at least one pair of electrodes extends is referred to as an electrode extending direction, the second support does not overlap the intersecting region when viewed from the electrode extending direction and when viewed from the electrode facing direction.

According to preferred embodiments of the present invention, it is possible to provide acoustic wave devices that each reduce or prevent deterioration of electrical characteristics due to an unnecessary wave.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic plan view of an acoustic wave device according to a first preferred embodiment of the present invention.

FIG. 2 is a schematic cross-sectional view taken along line I-I in FIG. 1.

FIG. 3 is a schematic cross-sectional view taken along line II-II in FIG. 1.

FIG. 4 is a schematic plan view illustrating a position which does not overlap an intersecting region when viewed from an electrode extending direction and when viewed from an electrode facing direction.

FIG. 5 is a schematic cross-sectional view illustrating a portion corresponding to FIG. 2 of an acoustic wave device according to a modification of the first preferred embodiment of the present invention.

FIG. 6 is a schematic plan view of an acoustic wave device according to a second preferred embodiment of the present invention.

FIG. 7 is a circuit diagram of the acoustic wave device according to the second preferred embodiment of the present invention.

FIG. 8 is a schematic plan view of an acoustic wave device according to a third preferred embodiment of the present invention.

FIG. 9 is a schematic plan view of an acoustic wave device according to a fourth preferred embodiment of the present invention.

FIG. 10 is a circuit diagram of the acoustic wave device according to the fourth preferred embodiment of the present invention.

FIG. 11A is a schematic perspective view illustrating an appearance of an acoustic wave device using bulk waves in a thickness shear mode, and FIG. 11B is a plan view illustrating an electrode structure on a piezoelectric layer.

FIG. 12 is a cross-sectional view of a portion taken along line A-A in FIG. 11A.

FIG. 13A is a schematic front cross-sectional view for explaining Lamb waves propagating through a piezoelectric film of an acoustic wave device, and FIG. 13B is a schematic front cross-sectional view for explaining bulk waves in the thickness shear mode propagating through the piezoelectric film in the acoustic wave device.

FIG. 14 is a diagram illustrating an amplitude direction of bulk waves in the thickness shear mode.

FIG. 15 is a diagram illustrating resonance characteristics of the acoustic wave device using bulk waves in the thickness shear mode.

FIG. 16 is a diagram illustrating a relationship between d/p and the fractional bandwidth as a resonator, when p is a center-to-center distance between adjacent electrodes and d is the thickness of the piezoelectric layer.

FIG. 17 is a plan view of an acoustic wave device using bulk waves in the thickness shear mode.

FIG. 18 is a diagram illustrating resonance characteristics of an acoustic wave device of a reference example in which a spurious emission appears.

FIG. 19 is a diagram illustrating a relationship between the fractional bandwidth and the phase rotation amount of the impedance of the spurious emission normalized by about 180 degrees as the magnitude of the spurious emission.

FIG. 20 is a diagram illustrating a relationship between d/2p and a metallization ratio MR.

FIG. 21 is a diagram illustrating a map of the fractional bandwidth with respect to the Euler angles (0°, θ, ψ) of LiNbO₃ when d/p is made as close to 0 as possible.

FIG. 22 is a partially cutaway perspective view illustrating an acoustic wave device using Lamb waves.

### DETAILED DESCRIPTION OF THE PREFERRED EMBODIMENTS

Hereinafter, preferred embodiments of the present invention will be described with reference to the drawings to clarify the present invention.

Each preferred embodiment described in the present specification is merely exemplary, and partial replacement or combination of configurations is possible between different preferred embodiments.

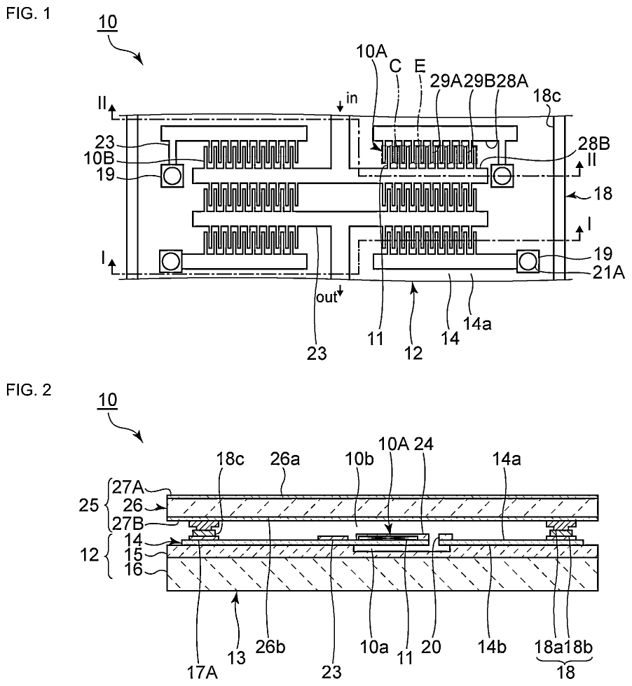

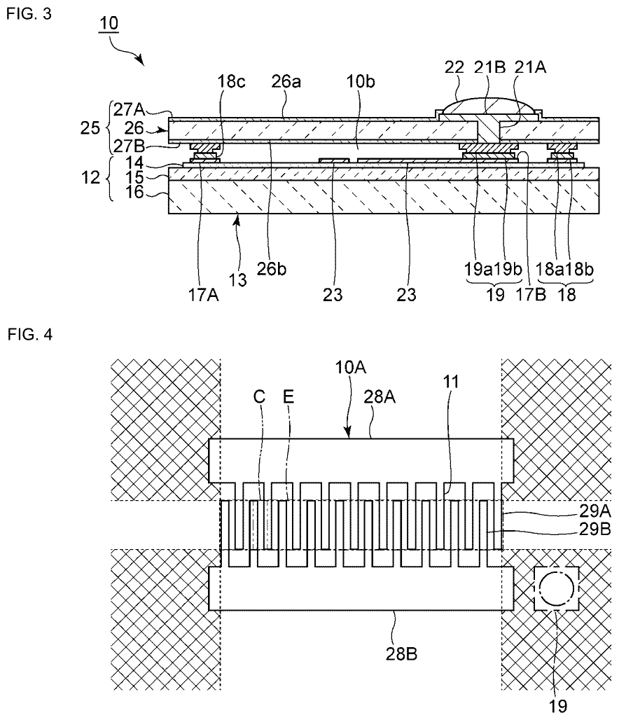

FIG. 1 is a schematic plan view of an acoustic wave device according to a first preferred embodiment of the present invention. FIG. 2 is a schematic cross-sectional view taken along line I-I in FIG. 1. FIG. 3 is a schematic cross-sectional view taken along line II-II in FIG. 1. In FIG. 1, a dielectric film to be described later is omitted. In FIG. 2, an IDT electrode to be described later is illustrated by a schematic drawing obtained by adding two diagonal lines to a rectangle. The same applies to other schematic cross-sectional views.

As illustrated in FIG. 1 and FIG. 2, an acoustic wave device 10 includes a piezoelectric substrate 12 and an IDT electrode 11 as a functional electrode. As illustrated in FIG. 2, the piezoelectric substrate 12 includes a support 13 and a piezoelectric layer 14. In the present preferred embodiment, the support 13 includes a support substrate 16 and an intermediate layer 15. The intermediate layer 15 is provided on the support substrate 16. The piezoelectric layer 14 is provided on the intermediate layer 15. However, the support 13 may include only the support substrate 16.

As the material of the support substrate 16, for example, a semiconductor such as silicon, ceramics such as aluminum oxide, or the like can be used. As the material of the intermediate layer 15, an appropriate dielectric such as, for example, silicon oxide or tantalum pentoxide can be used. The piezoelectric layer 14 is, for example, a lithium tantalate layer such as a LiTaO₃ layer or a lithium niobate layer such as a LiNbO₃ layer.

The piezoelectric layer 14 includes a first main surface 14a and a second main surface 14b. The first main surface 14a and the second main surface 14b face each other. Of the first main surface 14a and the second main surface 14b, the second main surface 14b is located on the support 13 side.

The support 13 includes a first cavity portion 10a. More specifically, a recess is provided in the intermediate layer 15. The piezoelectric layer 14 is provided on the intermediate layer 15 so as to close the recess. Thus, the first cavity portion 10a is provided. The first cavity portion 10a may be provided in the intermediate layer 15 and the support substrate 16, or may be provided only in the support substrate 16. The support 13 may include at least one first cavity portion 10a.

As illustrated in FIG. 1, a plurality of IDT electrodes 11 is provided on the first main surface 14a of the piezoelectric layer 14. Thus, a plurality of acoustic wave resonators are provided. Specifically, in the present preferred embodiment, six acoustic wave resonators are provided. The plurality of acoustic wave resonators include a first resonator 10A and a second resonator 10B. The acoustic wave device 10 in the present preferred embodiment is a filter device. The acoustic wave device 10 may include at least one IDT electrode 11. An acoustic wave device according to a preferred embodiment of the present invention may include at least one acoustic wave resonator.

As illustrated in FIG. 2, at least a portion of the IDT electrode 11 overlaps the first cavity portion 10a in plan view. To be more specific, in plan view, the IDT electrode 11 of each of the acoustic wave resonators may overlap another first cavity portion 10a or may overlap the same first cavity portion 10a. In this specification, a plan view refers to a view from a direction corresponding to the upper side in FIG. 2. Further, the plan view refers to a view along a direction in which a first support 18 and a lid portion 25 described later are stacked. In FIG. 1, for example, of the support substrate 16 and the piezoelectric layer 14, the piezoelectric layer 14 side is the upper side.

Returning to FIG. 1, the IDT electrode 11 includes a first busbar 28A, a second busbar 28B, a plurality of first electrode fingers 29A, and a plurality of second electrode fingers 29B. The first busbar 28A and the second busbar 28B face each other. One end of each of the plurality of first electrode fingers 29A is connected to the first busbar 28A. One end of each of the plurality of second electrode fingers 29B is connected to the second busbar 28B. The plurality of first electrode fingers 29A and the plurality of second electrode fingers 29B are interdigitated with each other. The first electrode fingers 29A and the second electrode fingers 29B are electrodes. The IDT electrode 11 may include a single-layer metal film or a multilayer metal film.

Hereinafter, a direction in which the adjacent first electrode finger 29A and the second electrode finger 29B face each other is referred to as an electrode facing direction. A direction in which the plurality of first electrode fingers 29A and the plurality of second electrode fingers 29B extend is referred to as an electrode extending direction. In the present preferred embodiment, the electrode facing direction and the electrode extending direction are orthogonal or substantially orthogonal to each other. When viewed from the electrode facing direction, a region in which the adjacent first electrode finger 29A and the second electrode finger 29B overlap each other is an intersecting region E.

The first support 18 and a plurality of second supports 19 are provided on the first main surface 14a of the piezoelectric layer 14. In the present preferred embodiment, each of the first support 18 and the second support 19 is a multilayer body including a plurality of metal layers. The first support 18 has a frame shape. On the other hand, the second support 19 has a columnar shape. The first support 18 surrounds the plurality of IDT electrodes 11 and the plurality of second supports 19. More particularly, the first support 18 includes an opening portion 18c. The plurality of IDT electrodes 11 and the plurality of second supports 19 are located in the opening portion 18c.

For example, one second support 19 among the plurality of second supports 19 is located in the vicinity of the first resonator 10A. Specifically, the second support 19 is located in a hatched region in FIG. 4. In FIG. 4, a region that is sandwiched between broken lines and is not hatched is a region overlapping the intersecting region E when viewed from the electrode extending direction or when viewed from the electrode facing direction. On the other hand, a region indicated by hatching is a region that does not overlap the intersecting region E both when viewed from the electrode extending direction and when viewed from the electrode facing direction.

As illustrated in FIG. 3, a frame-shaped electrode layer 17A is provided between the piezoelectric layer 14 and the first support 18. The electrode layer 17A surrounds the plurality of IDT electrodes 11 and the plurality of second supports 19 in plan view as the first support 18. However, the electrode layer 17A need not be provided. The lid portion 25 is provided on the first support 18 and the plurality of second supports 19 so as to close the opening portion 18c. As such, a second cavity portion 10b surrounded by the piezoelectric substrate 12, the electrode layer 17A, the first support 18, and the lid portion 25 is provided. The plurality of IDT electrodes 11 and the plurality of second supports 19 are arranged in the second cavity portion 10b.

As illustrated in FIG. 1, in the present preferred embodiment, the second support 19 is arranged so as not to overlap the intersecting region E both when viewed from the electrode extending direction and when viewed from the electrode facing direction. As a result, it is possible to reduce or prevent deterioration of electrical characteristics due to unnecessary waves. This will be explained below. Hereinafter, the first busbar 28A and the second busbar 28B may be simply referred to as a busbar. Similarly, the first electrode finger 29A and the second electrode finger 29B may be simply referred to as an electrode finger.

The IDT electrode 11 includes a plurality of excitation regions C. By applying an AC voltage to the IDT electrode 11, acoustic waves are excited in the plurality of excitation regions C. In the present preferred embodiment, each acoustic wave resonator is configured to allow bulk waves in a thickness shear mode such as, for example, a first order thickness shear mode to be used. Similar to the intersecting region E, the excitation region C is a region in which adjacent electrode fingers overlap each other when viewed from the electrode facing direction. Each of the excitation regions C is a region between a pair of electrode fingers. More specifically, the excitation region C is a region from the center of one electrode finger in the electrode facing direction to the center of the other electrode finger in the electrode facing direction. Therefore, the intersecting region E includes the plurality of excitation regions C.

In the acoustic wave resonator, a main mode may be excited and an unnecessary wave may be excited. The unnecessary wave includes a wave propagating on the surface of the piezoelectric substrate. The unnecessary wave propagates mainly in the electrode extending direction or the electrode facing direction.

On the other hand, in the present preferred embodiment, the second support 19 is provided so as not to overlap the intersecting region E both when viewed from the electrode extending direction and when viewed from the electrode facing direction. Therefore, an unnecessary wave propagating on the surface of the piezoelectric substrate 12 is less likely to collide with the second support 19. As such, it is possible to prevent the unnecessary wave from being reflected by the second support 19 and from reaching the acoustic wave resonator that has generated the unnecessary wave. Therefore, it is possible to reduce or prevent deterioration of the electrical characteristics of the acoustic wave device 10 due to the unnecessary wave. At least a portion of the second support 19 may be provided so as not to overlap the intersecting region E with respect to any one acoustic wave resonator when viewed from the electrode extending direction and when viewed from the electrode facing direction.

The second support 19 is preferably provided so as not to overlap the intersecting region E of the acoustic wave resonator having the shortest distance from the second support 19 both when viewed from the electrode extending direction and when viewed from the electrode facing direction. As a result, it is possible to effectively reduce or prevent the reflection of the unnecessary wave by the second support 19.

However, it is more preferable that the positional relationship between the second support 19 and the intersecting region E in all of the acoustic wave resonators including the first resonator 10A and the second resonator 10B are as described above. That is, it is more preferable that all of the second supports 19 are provided so as not to overlap all of the intersecting regions E both when viewed from the electrode extending direction and when viewed from the electrode facing direction. Accordingly, it is possible to more reliably reduce or prevent the deterioration of the electrical characteristics of the acoustic wave device 10 due to the unnecessary wave.

In the following, further details of the configuration of the present preferred embodiment will be described.

As illustrated in FIG. 2, a dielectric film 24 is provided on the piezoelectric substrate 12 so as to cover the IDT electrode 11. Thus, the IDT electrode 11 is less likely to be damaged. The dielectric film 24 may be made of, for example, silicon oxide, silicon nitride, silicon oxynitride, or the like. When the dielectric film 24 is made of silicon oxide, the frequency-temperature characteristics can be improved. On the other hand, when the dielectric film 24 is made of silicon nitride or the like, the dielectric film 24 can be used as a frequency adjustment film. The dielectric film 24 need not be provided.

A through-hole 20 is continuously provided in the piezoelectric layer 14 and the dielectric film 24. The through-hole 20 is provided so as to extend to the first cavity portion 10a. The through-hole 20 is used to remove a sacrificial layer in the intermediate layer 15 when the acoustic wave device 10 is manufactured. However, the through-hole 20 need not necessarily be provided.

The lid portion 25 includes a lid body 26, an insulating layer 27A, and an insulating layer 27B. The lid body 26 includes a first main surface 26a and a second main surface 26b. The first main surface 26a and the second main surface 26b face each other. Of the first main surface 26a and the second main surface 26b, the second main surface 26b is located on the piezoelectric substrate 12 side. The insulating layer 27A is provided on the first main surface 26a. The insulating layer 27B is provided on the second main surface 26b. In the present preferred embodiment, the main component of the lid body 26 is, for example, silicon. The material of the lid body 26 is not limited to the above, but preferably includes, for example, a semiconductor such as silicon as a main component. In this specification, the term “main component” refers to a component whose proportion exceeds 50% by weight. On the other hand, the insulating layer 27A and the insulating layer 27B are, for example, silicon-oxide layers.

As illustrated in FIG. 3, the lid portion 25 includes an under bump metal 21A. More specifically, a through-hole is provided in the lid portion 25. The through-hole is provided so as to extend to the second support 19. The under bump metal 21A is provided in the through-hole. One end of the under bump metal 21A is connected to the second support 19. An electrode pad 21B is connected to the other end of the under bump metal 21A. In the present preferred embodiment, the under bump metal 21A and the electrode pad 21B are integrally provided. However, the under bump metal 21A and the electrode pad 21B may be provided as separate bodies. A bump 22 is bonded to the electrode pad 21B.

More specifically, the insulating layer 27A covers the vicinity of the outer peripheral edge of the electrode pad 21B. The bump 22 is bonded to a portion of the electrode pad 21B that is not covered with the insulating layer 27A. The insulating layer 27A may extend between the electrode pad 21B and the lid body 26. Furthermore, the insulating layer 27A may extend between the under bump metal 21A and the lid body 26. The insulating layer 27A and the insulating layer 27B may be integrally provided via a through-hole of the lid body 26.

As described above, in the present preferred embodiment, each of the first support 18 and the second support 19 is a multilayer body including a plurality of metal layers. To be more specific, the first support 18 includes a first portion 18a and a second portion 18b. Of the first portion 18a and the second portion 18b, the first portion 18a is located on the lid portion 25 side, and the second portion 18b is located on the piezoelectric substrate 12 side. Similarly, the second support 19 also includes a first portion 19a and a second portion 19b. Of the first portion 19a and the second portion 19b, the first portion 19a is located on the lid portion 25 side, and the second portion 19b is located on the piezoelectric substrate 12 side. Each of the first portion 18a and the first portion 19a is made of, for example, Au or the like. Each of the second portion 18b and the second portion 19b is made of, for example, Al or the like. In this specification, a case where a certain member is made of a certain material includes a case where trace impurities are included to such an extent that electrical characteristics of the acoustic wave device are not deteriorated.

As illustrated in FIG. 1, in the present preferred embodiment, acoustic wave resonators adjacent to each other in the electrode extending direction share a busbar. The shared busbar becomes a first busbar in one acoustic wave resonator, and becomes a second busbar in the other acoustic wave resonator.

A plurality of wiring electrodes 23 are provided on the piezoelectric substrate 12. Some of the plurality of wiring electrodes 23 connect the IDT electrodes 11 to each other. Another portion of the plurality of wiring electrodes 23 electrically connects the IDT electrode 11 and the second support 19. To be more specific, as illustrated in FIG. 3, a conductive film 17B is provided on the piezoelectric substrate 12. The second support 19 is provided on the conductive film 17B. Thus, the wiring electrode 23 is electrically connected to the second support 19 via the conductive film 17B. The plurality of IDT electrodes 11 are electrically connected to the outside via the wiring electrode 23, the conductive film 17B, the second support 19, the under bump metal 21A, the electrode pad 21B, and the bump 22.

The plurality of second supports 19 may include the second support 19 that is not connected to the under bump metal 21A.

The functional electrode in the present preferred embodiment is the IDT electrode 11. The functional electrode may include at least one pair of electrode fingers. In this case, for example, bulk waves in the thickness shear mode can be used.

On the other hand, the plurality of acoustic wave resonators of the acoustic wave device 10 may be configured to allow plate waves to be used, for example. When each acoustic wave resonator uses plate waves, the intersecting region E of the IDT electrode 11 is an excitation region. In this case, as the material of the piezoelectric layer 14, for example, lithium niobate, lithium tantalate, zinc oxide, aluminum nitride, crystal, lead zirconate titanate (PZT), or the like can be used.

Preferred configurations in the present preferred embodiment will be described below.

Preferably, at least one second support 19 is provided between the acoustic wave resonator and the first support 18 and is not provided between the plurality of acoustic wave resonators. In this case, it is easy to reduce or prevent the reflection of an unnecessary wave due to the provision of the second support 19.

The conductive film 17B and the wiring electrode 23 are preferably made of the same material. In the case where the wiring electrode 23 is connected to the conductive film 17B, the conductive film 17B and the wiring electrode 23 are preferably integrally provided. As such, productivity can be improved. The conductive film 17B is not necessarily connected to the wiring electrode 23.

As illustrated in FIG. 2, when a dimension along a direction in which the piezoelectric substrate 12, the first support 18, and the lid portion 25 are stacked is referred to as a height, it is preferable that the height of the second cavity portion 10b is higher than the height of the first cavity portion 10a. In this case, even when the piezoelectric layer 14 is deformed in a convex shape from the first cavity portion 10a side to the second cavity portion 10b side, the piezoelectric layer 14 is less likely to adhere to the lid portion 25.

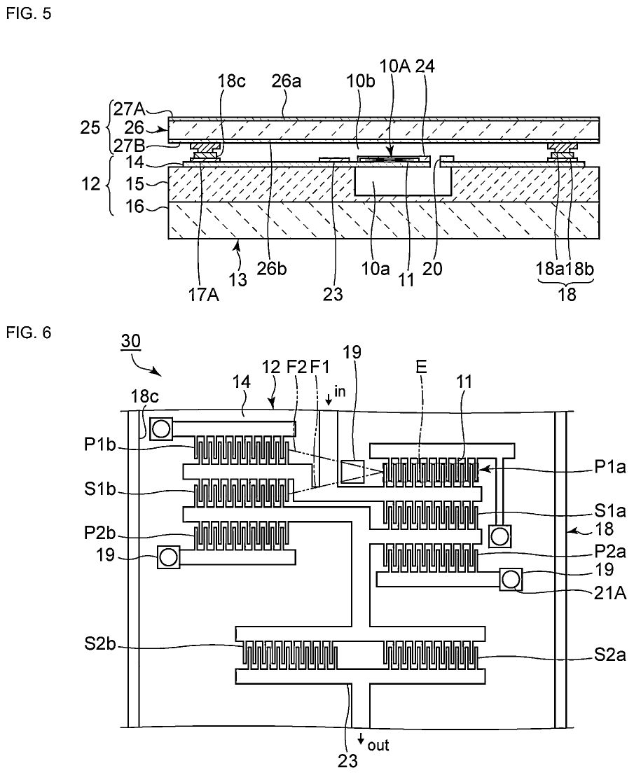

However, a relationship between the heights of the first cavity portion 10a and the second cavity portion 10b is not limited to the above. In the modification of the first preferred embodiment illustrated in FIG. 5, the height of the first cavity portion 10a is higher than the height of the second cavity portion 10b. In this case, even when the piezoelectric layer 14 is deformed in a convex shape from the second cavity portion 10b side to the first cavity portion 10a side, the piezoelectric layer 14 is less likely to adhere to the support 13. In addition, as in the first preferred embodiment, it is possible to scatter unnecessary waves and to reduce or prevent deterioration of electrical characteristics due to the unnecessary waves.

As illustrated in FIG. 3, in the first preferred embodiment, the first support 18 and the plurality of second support 19 are provided on the piezoelectric layer 14 of the piezoelectric substrate 12. However, at least a portion of the first support 18 may be provided in a portion of the piezoelectric substrate 12 where the piezoelectric layer 14 is not provided. Similarly, at least a portion of the second support 19 may be provided in a portion of the piezoelectric substrate 12 where the piezoelectric layer 14 is not provided. For example, at least a portion of the first support 18 or the second support 19 may be provided on the intermediate layer 15 or the support substrate 16.

In the first preferred embodiment, the first support 18 and the plurality of second supports 19 are a multilayer body of metal layers. The first support 18 and the second support 19 may be made of resin, for example. In this case as well, it is possible to reduce or prevent reflection of an unnecessary wave by the second support 19. Therefore, it is possible to reduce or prevent deterioration of electrical characteristics due to the unnecessary wave. When the second support 19 is made of resin, the under bump metal 21A may be provided so as to pass through the second support 19.

The lid body 26 includes, for example, a semiconductor as a main component. The lid portion 25 may be made of resin, for example. Further, when the first support 18 and the second support 19 are made of resin, it is preferable that the first support 18, the second support 19, and the lid portion 25 are integrally made of the same resin material. As such, productivity can be improved.

In the first preferred embodiment, the IDT electrode 11 is provided on the first main surface 14a of the piezoelectric layer 14. However, the IDT electrode 11 may be provided on the second main surface 14b of the piezoelectric layer 14. In this case, the IDT electrode 11 is located, for example, in the first cavity portion 10a.

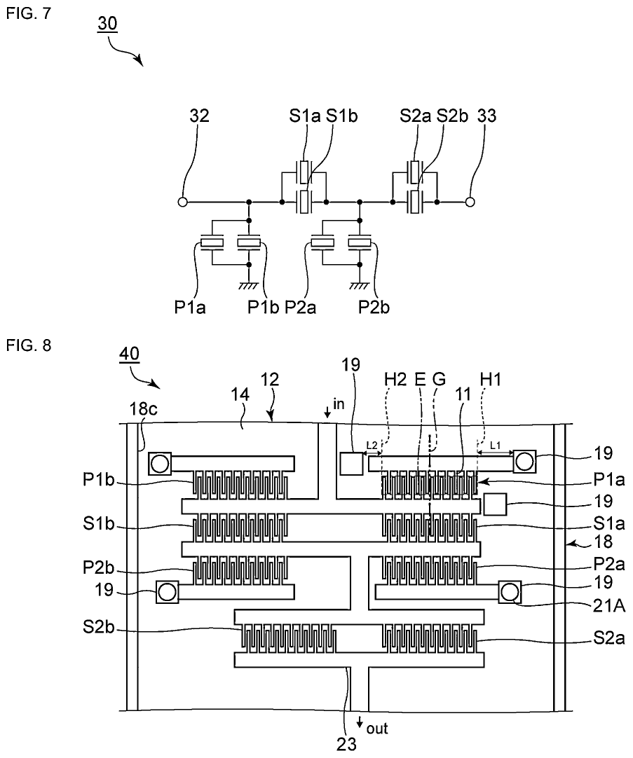

FIG. 6 is a schematic plan view of an acoustic wave device according to a second preferred embodiment of the present invention. FIG. 7 is a circuit diagram of the acoustic wave device according to the second preferred embodiment.

As illustrated in FIG. 6, the present preferred embodiment is different from the first preferred embodiment in the arrangement of the plurality of acoustic wave resonators and the arrangement of the plurality of second supports 19. The present preferred embodiment is also different from the first preferred embodiment in the circuit configuration. Except for the above points, an acoustic wave device 30 of the present preferred embodiment has the same or substantially the same configuration as that of the acoustic wave device 10 of the first preferred embodiment.

Also in the present preferred embodiment, the second support 19 is arranged so as not to overlap an intersecting region E of the IDT electrode 11 of each acoustic wave resonator both when viewed in an electrode extending direction and when viewed in an electrode facing direction. Therefore, similar to the first preferred embodiment, it is possible to reduce or prevent reflection of an unnecessary wave and to reduce or prevent deterioration of electrical characteristics due to the unnecessary wave.

As illustrated in FIG. 7, the acoustic wave device 30 is a ladder filter, for example. The acoustic wave device 30 includes an input terminal 32, an output terminal 33, a plurality of series arm resonators, and a plurality of parallel arm resonators. The input terminal 32 and the output terminal 33 may include electrode pads or may include wirings, for example. In the acoustic wave device 30, a signal is input from the input terminal 32.

The plurality of series arm resonators and the plurality of parallel arm resonators of the acoustic wave device 30 are each divided acoustic wave resonators. The plurality of series arm resonators are, to be specific, a series arm resonator S1a, a series arm resonator S1b, a series arm resonator S2a, and a series arm resonator S2b. The series arm resonators S1a and S1b are resonators obtained by dividing one series arm resonator in parallel. Similarly, the series arm resonators S2a and S2b are resonators obtained by dividing one series arm resonator in parallel. The series arm resonators S1a and S1b and the series arm resonators S2a and S2b are connected in series with each other between the input terminal 32 and the output terminal 33.

The plurality of parallel arm resonators are, to be specific, a parallel arm resonator P1a, a parallel arm resonator P1b, a parallel arm resonator P2a, and a parallel arm resonator P2b. The parallel arm resonators P1a and P1b are resonators obtained by dividing one parallel arm resonator in parallel. Similarly, the parallel arm resonators P2a and P2b are resonators obtained by dividing one parallel arm resonator in parallel. The parallel arm resonators P1a and P1b are connected in parallel with each other between the input terminal 32 and a ground potential. The parallel arm resonator P2a and the parallel arm resonator P2b are connected in parallel with each other between the ground potential and a connection point between the series arm resonator S1a and the series arm resonator S2a.

The circuit configuration of the acoustic wave device 30 is not limited to that described above. Each series arm resonator and each parallel arm resonator may be a resonator divided in series. Alternatively, each series arm resonator and each parallel arm resonator need not be a divided resonator. When the acoustic wave device 30 is a ladder filter, the plurality of resonators may include at least one series arm resonator and at least one parallel arm resonator.

As illustrated in FIG. 6, each of the plurality of parallel arm resonators is connected to the second support 19. In the present preferred embodiment, the plurality of parallel arm resonators are connected to the ground potential via the second support 19.

The series arm resonator S1b and the parallel arm resonator P1b are adjacent to each other in the electrode extending direction. The series arm resonator S1b and the parallel arm resonator P1b are adjacent to the parallel arm resonator Pia in the electrode facing direction. The second support 19 is provided between the series arm resonator S1b and the parallel arm resonator P1b and the parallel arm resonator Pia. As such, heat generated from the IDT electrode 11 of each of the series arm resonator S1b, the parallel arm resonator P1b, and the parallel arm resonator Pia can be dissipated to the outside via the second support 19. Therefore, heat dissipation can be improved. Since the second support 19 is arranged between at least two acoustic wave resonators, the heat dissipation can be improved.

A line F1 connecting the series arm resonator S1b and the parallel arm resonator Pia extends in a direction intersecting both of the electrode extending direction and the electrode facing direction. The second support 19 is located on the line F1. Similarly, a line F2 connecting the parallel arm resonator P1b and the parallel arm resonator Pia extends in a direction intersecting both the electrode extending direction and the electrode facing direction. The second support 19 is located on the line F2. The second support 19 does not overlap the intersecting region E of each of the series arm resonator S1b and the parallel arm resonator P1b both when viewed in the electrode extending direction and when viewed in the electrode facing direction. On the other hand, the second support 19 overlaps the intersecting region E of the parallel arm resonator Pia when viewed from the electrode facing direction.

In this case as well, it is possible to reduce or prevent reflection of unnecessary waves, which are generated in the series arm resonator S1b and the parallel arm resonator P1b, by the second support 19. Therefore, it is possible to reduce or prevent deterioration of electrical characteristics due to an unnecessary wave.

Furthermore, in the present preferred embodiment, the wiring electrode 23 is provided between the second support 19 and the series arm resonator S1b and the parallel arm resonator P1b. In this case, heat dissipation can be improved.

FIG. 8 is a schematic plan view of an acoustic wave device according to a third preferred embodiment of the present invention.

The present preferred embodiment is different from the second preferred embodiment in the arrangement of the plurality of acoustic wave resonators and the arrangement of the plurality of second supports 19. Except for the above-described points, an acoustic wave device 40 of the present preferred embodiment has the same or substantially the same configuration as that of the acoustic wave device 30 of the second preferred embodiment.

As illustrated in FIG. 8, also in the present preferred embodiment, the second support 19 does not overlap an intersecting region E of the IDT electrode 11 of each acoustic wave resonator both when viewed from an electrode extending direction and when viewed from an electrode facing direction. Thus, as in the second preferred embodiment, reflection of the unnecessary wave by the second support 19 can be reduce or prevented, and deterioration of electrical characteristics due to an unnecessary wave can be reduce or prevented.

In the present preferred embodiment, the plurality of second supports 19 sandwich the parallel arm resonator P1a in the electrode facing direction. As a result, heat dissipation can be effectively improved. Each of the plurality of second supports 19 is preferably arranged so as not to overlap the intersecting region E of the parallel arm resonator P1a both when viewed from the electrode extending direction and when viewed from the electrode facing direction. As such, it is possible to more reliably reduce or prevent the reflection of the unnecessary wave.

There are 1.5 pairs of second supports 19 sandwiching the parallel arm resonator P1a. The expression “being sandwiched between 1.5 pairs of second supports 19 in the electrode facing direction” means that two second supports 19 are arranged on one side in the electrode facing direction and one second support 19 is arranged on the other side in the electrode facing direction so that the acoustic wave resonator is sandwiched therebetween. The number of pairs of second supports 19 sandwiching the acoustic wave resonator is not limited to 1.5, and may be one or two or more.

In the present preferred embodiment, the plurality of second supports 19 is arranged asymmetrically to sandwich the parallel arm resonator P1a. The term “asymmetric” means that the arrangement of the plurality of second supports 19 is not line-symmetric when an axis passing through the center of the intersecting region E in the electrode facing direction and extending in the electrode extending direction is set as a symmetry axis G in plan view.

In particular, of the 1.5 pairs of second supports 19 sandwiching the parallel arm resonator P1a, one pair of second supports 19 does not sandwich the intersecting region E of the parallel arm resonator P1a in the electrode extending direction. One of the second supports 19 is closer to the intersecting region E than the other second support 19 in the electrode extending direction. In this way, they are asymmetric in the electrode facing direction.

In addition to this, the one pair of second supports 19 is also asymmetric in the electrode facing direction. To be more specific, it is assumed that a distance L1 is a distance between one second support 19 of the second supports 19 sandwiching the parallel arm resonator Pia and a straight line H1 in FIG. 8. The straight line H1 is an extended line in the electrode extending direction of the electrode finger located at one end of the intersecting region E in the electrode facing direction in the parallel arm resonator Pia. It is assumed that a distance L2 is a distance between the other second support 19 and a straight line H2 in FIG. 8. The straight line H2 is an extended line in the electrode extending direction of the electrode finger located at the other end of the above intersecting region E. As illustrated in FIG. 8, L1≠L2 is satisfied.

That is, in the present preferred embodiment, the arrangement of the one pair of second supports 19 sandwiching the parallel arm resonator Pia is asymmetric in both the electrode facing direction and the electrode extending direction. When the arrangement of the one pair of second supports 19 is asymmetric, the arrangement may be asymmetric in at least one of the electrode facing direction and the electrode extending direction. In this case, even when a portion of the unnecessary waves extends to each of the second supports 19, the phases of the unnecessary waves can be shifted from each other. Therefore, it is possible to reduce or prevent the influence of the unnecessary waves on the electrical characteristics.

The arrangement of the centers of the one pair of second supports 19 is preferably asymmetric in at least one of the electrode facing direction and the electrode extending direction. In this case, it is possible to reduce or prevent the influence of the unnecessary waves on the electrical characteristics.

In the present preferred embodiment, the other pair of second supports 19 of the above 1.5 pairs of second supports 19 sandwiching the parallel arm resonator Pia is also arranged asymmetrically in both the electrode facing direction and the electrode extending direction. Therefore, it is possible to further improve the heat dissipation while reduce or preventing the influence of the unnecessary waves on the electrical characteristics.

As illustrated in FIG. 8, of the 1.5 pairs of second supports 19 sandwiching the parallel arm resonator P1a, one pair of second supports 19 sandwiches the parallel arm resonator P1a in the electrode facing direction. On the one hand, the other pair of second supports 19 of the 1.5 pairs of second supports 19 sandwiches the parallel arm resonator P1a in a direction intersecting the electrode facing direction and the electrode extending direction. One pair of second supports 19 sandwiching the parallel arm resonator P1a may sandwich the parallel arm resonator P1a in the electrode extending direction.

On the other hand, as illustrated in FIG. 8, the second support 19 is provided on one side of the series arm resonator S1a in the electrode facing direction. The series arm resonator S1a is not sandwiched between the plurality of second supports 19. As a result, it is possible to reduce the portion in which the second support 19 is arranged, and to reduce the area of the piezoelectric substrate 12. Such a configuration is particularly preferable in a circuit configuration in which the parallel arm resonator P1a is required to have higher electric power handling capability than the series arm resonator S1a. Specifically, it is possible to increase the electric power handling capability of the acoustic wave device 40 as a whole and to reduce the size of the acoustic wave device 30.

In the circuit, the parallel arm resonator P1a is one of the acoustic wave resonators closest to the input terminal 32 among the plurality of acoustic wave resonators. In this case, the parallel arm resonator P1a is particularly likely to be required to have electric power handling capability.

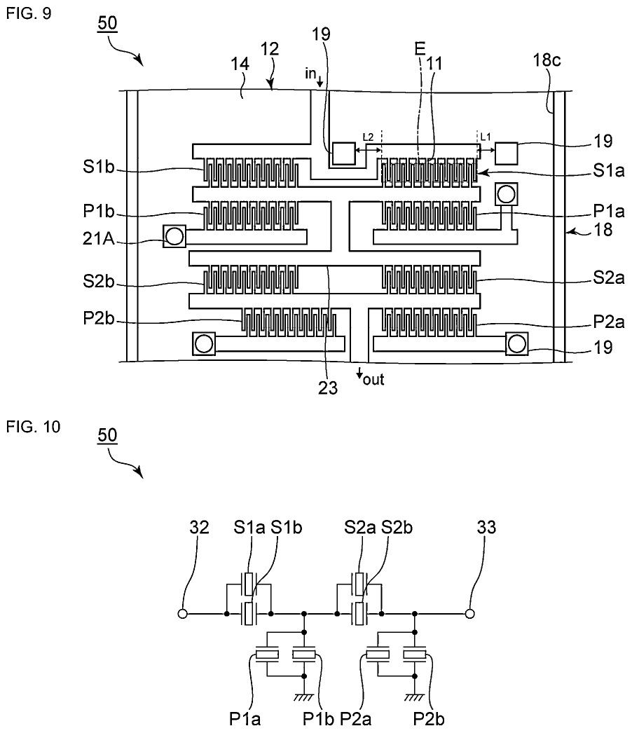

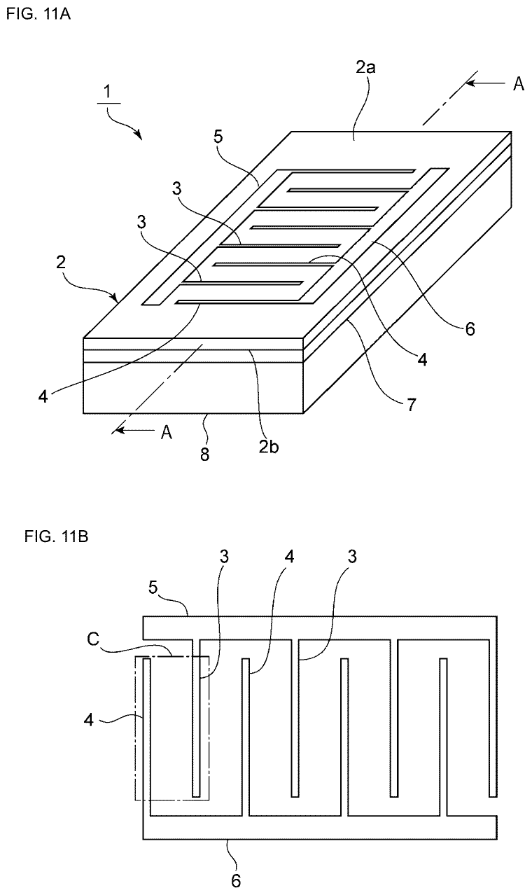

FIG. 9 is a schematic plan view of an acoustic wave device according to a fourth preferred embodiment of the present invention. FIG. 10 is a circuit diagram of the acoustic wave device according to the fourth preferred embodiment.

As illustrated in FIG. 9, the present preferred embodiment is different from the second preferred embodiment in the arrangement of the plurality of acoustic wave resonators and the arrangement of the plurality of second supports 19. As illustrated in FIG. 10, a circuit configuration of the present preferred embodiment is different from that of the second preferred embodiment in the arrangement of the plurality of parallel arm resonators. Except for the above-described points, an acoustic wave device 50 of the present preferred embodiment has the same or substantially the same configuration as that of the acoustic wave device 30 of the second preferred embodiment.

In the acoustic wave device 50, the parallel arm resonators P1a and P1b are connected in parallel to each other between a ground potential and a connection point between the series arm resonators S1a and S2a. The parallel arm resonator P2a and the parallel arm resonator P2b are connected in parallel with each other between the output terminal 33 and the ground potential.

Referring back to FIG. 9, in the present preferred embodiment, the second support 19 is arranged so as not to overlap an intersecting region E of the IDT electrode 11 of the plurality of acoustic wave resonators both when viewed from an electrode extending direction and when viewed from an electrode facing direction. Thus, as in the second preferred embodiment, reflection of an unnecessary wave by the second support 19 can be reduce or prevented, and deterioration of electrical characteristics due to the unnecessary wave can be reduce or prevented.

In the acoustic wave device 50, the plurality of second supports 19 sandwich the series arm resonator S1a. As such, heat generated in the series arm resonator S1a can be effectively dissipated. On the other hand, the second support 19 is provided on one side of the parallel arm resonator P1a in the electrode facing direction. The parallel arm resonator P1a is not sandwiched between the plurality of second supports 19. As a result, it is possible to reduce the portion in which the second support 19 is arranged, and to reduce the area of the piezoelectric substrate 12. Such a configuration is particularly preferable in a circuit configuration in which the series arm resonator S1a is required to have higher electric power handling capability than the parallel arm resonator P1a. Specifically, it is possible to increase the electric power handling capability of the acoustic wave device 50 as a whole and to reduce the size of the acoustic wave device 50.

In the circuit, the series arm resonator S1a is one of the acoustic wave resonators closest to the input terminal 32 among the plurality of acoustic wave resonators. In this case, the series arm resonator S1a is particularly likely to be required to have electric power handling capability.

Also in the present preferred embodiment, in a pair of second supports 19 among the plurality of second supports 19 sandwiching the series arm resonator S1a, L1≠L2 is satisfied. That is, the pair of second supports 19 is asymmetric at least in the electrode facing direction. Therefore, even when a portion of the unnecessary waves reaches each of the second supports 19, the phases of the unnecessary waves can be shifted from each other. Therefore, it is possible to reduce or prevent the influence of the unnecessary waves on the electrical characteristics.

Hereinafter, a thickness shear mode and plate waves will be described in detail. The electrodes in the following examples correspond to the electrode fingers described above. The support in the following examples corresponds to a support substrate.

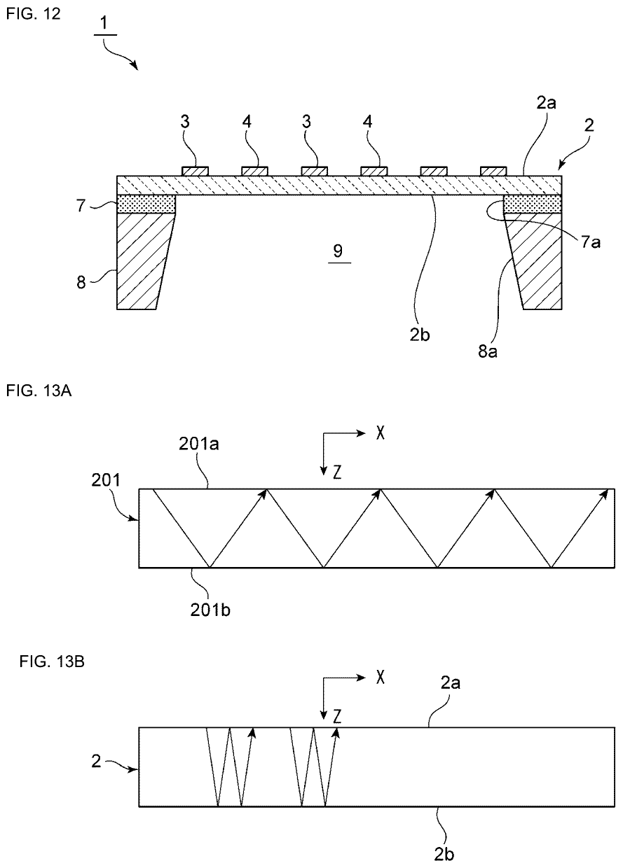

FIG. 11A is a schematic perspective view illustrating an appearance of an acoustic wave device using bulk waves in the thickness shear mode, FIG. 11B is a plan view illustrating an electrode structure on a piezoelectric layer, and FIG. 12 is a cross-sectional view of a portion taken along line A-A in FIG. 11A.

The acoustic wave device 1 includes a piezoelectric layer 2 made of, for example, LiNbO₃. The piezoelectric layer 2 may be made of, for example, LiTaO₃. The cut angle of the LiNbO₃ and the LiTaO₃ is Z-cut, but may be rotated Y-cut or X-cut. In order to effectively excite the thickness shear mode, the thickness of the piezoelectric layer 2 is preferably, for example, equal to or more than about 40 nm and equal to or less than about 1000 nm, and more preferably equal to or more than about 50 nm and equal to or less than about 1000 nm, but is not particularly limited. The piezoelectric layer 2 includes first and second main surfaces 2a and 2b facing each other. An electrode 3 and an electrode 4 are provided on the first main surface 2a. Here, the electrode 3 is an example of a “first electrode”, and the electrode 4 is an example of a “second electrode”. In FIGS. 11A and 11B, the plurality of electrodes 3 are connected to a first busbar 5. The plurality of electrodes 4 are connected to a second busbar 6. The plurality of electrodes 3 and the plurality of electrodes 4 are interdigitated with each other. The electrode 3 and the electrode 4 have a rectangular or substantially rectangular shape and have a length direction. The electrode 3 and the adjacent electrode 4 face each other in a direction orthogonal or substantially orthogonal to the length direction. The length direction of the electrodes 3 and 4 and the direction orthogonal or substantially orthogonal to the length direction of the electrodes 3 and 4 are both directions intersecting a thickness direction of the piezoelectric layer 2. Therefore, it can also be said that the electrode 3 and the adjacent electrode 4 face each other in the direction intersecting the thickness direction of the piezoelectric layer 2. Further, the length direction of the electrodes 3 and 4 may be replaced with the direction orthogonal or substantially orthogonal to the length direction of the electrodes 3 and 4 illustrated in FIGS. 11A and 11B. That is, in FIGS. 11A and 11B, the electrodes 3 and 4 may be extended in the direction in which the first busbar 5 and the second busbar 6 extend. In this case, the first busbar 5 and the second busbar 6 extend in the direction in which the electrodes 3 and 4 extend in FIGS. 11A and 11B. A plurality of pairs of structures, a pair of the electrode 3 connected to one potential and the electrode 4 connected to the other potential being adjacent to each other, is provided in the direction orthogonal or substantially orthogonal to the length direction of the electrodes 3 and 4. Here, the electrode 3 and the electrode 4 being adjacent to each other refers not to a case where the electrode 3 and the electrode 4 are arranged so as to be in direct contact with each other, but to a case where the electrode 3 and the electrode 4 are arranged with a gap therebetween. In addition, when the electrode 3 and the electrode 4 are adjacent to each other, an electrode connected to a hot electrode or a ground electrode, including the other electrodes 3 and 4, is not arranged between the electrode 3 and the electrode 4. The number of pairs need not be integer pairs, but may be 1.5 pairs, 2.5 pairs, and the like. The center-to-center distance between the electrodes 3 and 4, that is, a pitch is preferably in the range of, for example, equal to or more than about 1 μm and equal to or less than about 10 μm. In addition, the widths of the electrodes 3 and 4, that is, the dimensions of the electrodes 3 and 4 in the facing direction are preferably in a range of, for example, equal to or more than about 50 nm and equal to or less than about 1000 nm, and more preferably in a range of equal to or more than about 150 nm and equal to or less than about 1000 nm. The center-to-center distance between the electrodes 3 and 4 is the distance between the center of the dimension (width dimension) of the electrode 3 in the direction orthogonal or substantially orthogonal to the length direction of the electrode 3 and the center of the dimension (width dimension) of the electrode 4 in the direction orthogonal or substantially orthogonal to the length direction of the electrode 4.

In addition, since the acoustic wave device 1 uses a Z-cut piezoelectric layer, the direction orthogonal or substantially orthogonal to the length direction of the electrodes 3 and 4 is a direction orthogonal or substantially orthogonal to a polarization direction of the piezoelectric layer 2. This is not the case when a piezoelectric body having another cut angle is used as the piezoelectric layer 2. Here, “orthogonal” is not limited to strictly orthogonal but may be substantially orthogonal (an angle formed by a direction orthogonal to the length direction of the electrodes 3 and 4 and the polarization direction is within a range of about 90°±10°, for example).

A support 8 is stacked on the second main surface 2b side of the piezoelectric layer 2 via an insulating layer 7. The insulating layer 7 and the support 8 have a frame shape, and include through-holes 7a and 8a as illustrated in FIG. 12. Thus, a cavity portion 9 is provided. The cavity portion 9 is provided so as not to interfere with the vibration of an excitation region C of the piezoelectric layer 2. Therefore, the support 8 is stacked on the second main surface 2b via the insulating layer 7 at a position not overlapping a portion in which at least one pair of electrodes 3 and 4 is provided. The insulating layer 7 need not be provided. Therefore, the support 8 can be directly or indirectly stacked on the second main surface 2b of the piezoelectric layer 2.

The insulating layer 7 is made of, for example, silicon oxide. However, in addition to silicon oxide, an appropriate insulating material such as, for example, silicon oxynitride or alumina may be used. The support 8 is made of, for example, Si. The plane orientation of the surface of Si on the piezoelectric layer 2 side may be (100), (110), or (111). It is preferable that Si of the support 8 has a high resistance of a resistivity of, for example, equal to or more than about 4 kΩcm. However, the support 8 can also be provided using an appropriate insulating material or semiconductor material.

Examples of the material of the support 8 include, for example, piezoelectric materials such as aluminum oxide, lithium tantalate, lithium niobate, and crystal; various ceramics such as alumina, magnesia, sapphire, silicon nitride, aluminum nitride, silicon carbide, zirconia, cordierite, mullite, steatite, and forsterite; dielectrics such as diamond and glass; and semiconductors such as gallium nitride.

The plurality of electrodes 3 and 4 and the first and second busbars 5 and 6 are made of an appropriate metal or alloy such as, for example, Al or an AlCu alloy. In the present preferred embodiment, the electrodes 3 and 4 and the first and second busbars 5 and 6 have a structure in which, for example, an Al film is stacked on a Ti film. An adhesion layer other than the Ti film may be used.

At the time of driving, an AC voltage is applied between the plurality of electrodes 3 and the plurality of electrodes 4. More specifically, an AC voltage is applied between the first busbar 5 and the second busbar 6. As such, it is possible to obtain resonance characteristics using bulk waves in the thickness shear mode excited in the piezoelectric layer 2. In addition, in the acoustic wave device 1, when the thickness of the piezoelectric layer 2 is defined as d and the center-to-center distance between any adjacent electrodes 3 and 4 of the plurality of pairs of electrodes 3 and 4 is defined as p, d/p is, for example, equal to or less than about 0.5. Therefore, the bulk waves in the thickness shear mode are effectively excited, and good resonance characteristics can be obtained. More preferably, d/p is, for example, equal to or less than about 0.24, in which case even better resonance characteristics can be obtained.

Since the acoustic wave device 1 has the above-described configuration, even when the number of pairs of the electrodes 3 and 4 is reduced in order to achieve a reduction in size, a decrease in a Q value is less likely to occur. This is because the propagation loss is small even when the number of electrode fingers in the reflectors on both sides is reduced. In addition, the number of above electrode fingers can be reduced by using the bulk waves in the thickness shear mode. The difference between Lamb waves used in the acoustic wave device and the bulk waves in the thickness shear mode will be described with reference to FIGS. 13A and 13B.

FIG. 13A is a schematic front cross-sectional view for explaining Lamb waves propagating through a piezoelectric film of an acoustic wave device as described in Japanese Unexamined Patent Application Publication No. 2012-257019. Here, a wave propagates through a piezoelectric film 201 as indicated by an arrow. In the piezoelectric film 201, a first main surface 201a and a second main surface 201b face each other, and a thickness direction connecting the first main surface 201a and the second main surface 201b is a Z-direction. An X-direction is a direction in which the electrode fingers of the IDT electrode are arranged. As illustrated in FIG. 13A, in the Lamb waves, the wave propagates in the X-direction as illustrated. Although the piezoelectric film 201 vibrates as a whole, since the wave propagates in the X-direction because of the plate wave, reflectors are provided on both sides of the IDS electrode to obtain resonance characteristics. Therefore, a propagation loss of the wave occurs, and the Q value decreases when the size is reduced, that is, when the number of pairs of electrode fingers is reduced.

On the other hand, as illustrated in FIG. 13B, in the acoustic wave device 1, since the vibration displacement is in the thickness shear direction, the wave propagates substantially in the direction connecting the first main surface 2a and the second main surface 2b of the piezoelectric layer 2, that is, in the Z-direction, and resonates. Thus, the X-direction component of the wave is significantly smaller than the Z-direction component. Since resonance characteristics are obtained by the propagation of the wave in the Z-direction, propagation loss is less likely to occur even when the number of electrode fingers of the reflector is reduced. Furthermore, even when the number of electrode pairs of electrodes 3 and 4 is reduced in order to further reduce the size, the Q value is less likely to decrease.

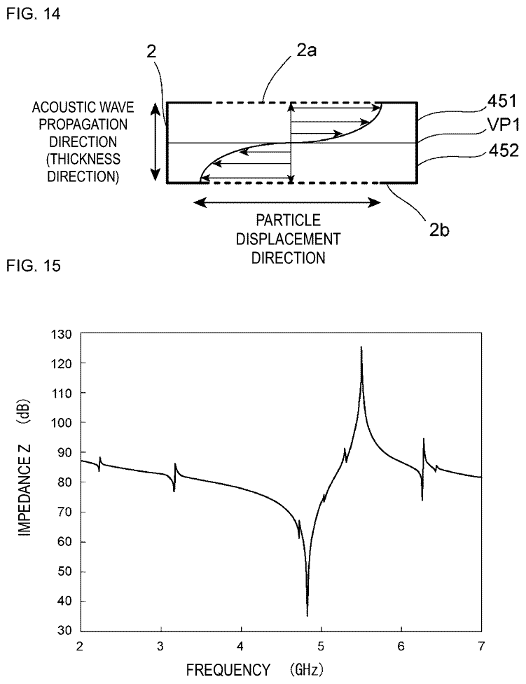

As illustrated in FIG. 14, amplitude directions of the bulk waves in the thickness shear mode are opposite between a first region 451 included in the excitation region C of the piezoelectric layer 2 and a second region 452 included in the excitation region C. FIG. 14 schematically illustrates bulk waves when a voltage is applied between the electrode 3 and the electrode 4 so that the electrode 4 has a higher potential than the electrode 3. The first region 451 is a region of the excitation region C between the first main surface 2a and a virtual plane VP1 that is orthogonal or substantially orthogonal to the thickness direction of the piezoelectric layer 2 and divides the piezoelectric layer 2 into two parts. The second region 452 is a region of the excitation region C between the virtual plane VP1 and the second main surface 2b.

As described above, in the acoustic wave device 1, at least one pair of electrodes of the electrode 3 and the electrode 4 is provided. However, since waves are not propagated in the X-direction, the number of pairs of electrodes of the electrodes 3 and 4 does not need to be plural. That is, at least one pair of electrodes may be provided.

For example, the electrode 3 is an electrode connected to a hot potential, and the electrode 4 is an electrode connected to the ground potential. However, the electrode 3 may be connected to the ground potential and the electrode 4 may be connected to the hot potential. In the present preferred embodiment, as described above, at least one pair of electrodes is an electrode connected to the hot potential or an electrode connected to the ground potential, and a floating electrode is not provided.

FIG. 15 is a diagram illustrating resonance characteristics of the acoustic wave device illustrated in FIG. 12. Design parameters of the acoustic wave device 1 having this resonance characteristic are as follows.
Piezoelectric layer 2: LiNbO₃ having Euler angles (0°, 0°, 90°), thickness=about 400 nm.

When viewed in a direction orthogonal to the length direction of the electrodes 3 and 4, the length of the region in which the electrodes 3 and 4 overlap, that is, the excitation region C=about 40 μm, the number of pairs of electrodes including the electrodes 3 and 4=21 pairs, the distance between the centers of the electrodes=about 3 μm, the widths of the electrodes 3 and 4=about 500 nm, and d/p=about 0.133.
Insulating layer 7: silicon oxide film having thickness of about 1 μm.
Support 8: Si.

The length of the excitation region C is a dimension of the excitation region C along the length direction of the electrodes 3 and 4.

In the present preferred embodiment, inter-electrode distances of the electrode pairs the electrodes 3 and 4 were all equal or substantially equal in a plurality of pairs. That is, the electrodes 3 and the electrodes 4 were arranged at equal or substantially equal pitches.

As is clear from FIG. 15, good resonance characteristics in which a fractional bandwidth is about 12.5%, for example, are obtained even though no reflector is provided.

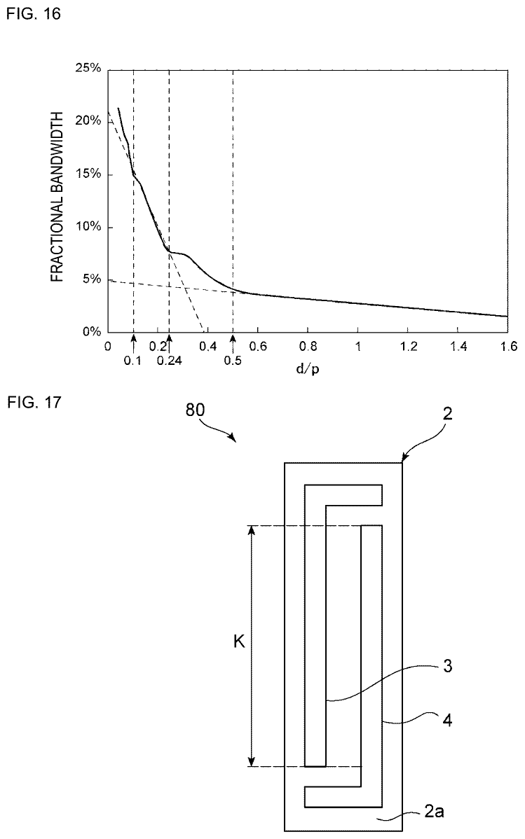

When the thickness of the above piezoelectric layer 2 is defined as d and the distance between the centers of the electrode 3 and the electrode 4 is defined as p, d/p is preferably, for example, equal to or less than about 0.5 and more preferably equal to or less than about 0.24 in the present preferred embodiment as described above. This will be described with reference to FIG. 16.

A plurality of acoustic wave devices were obtained in the same manner as the acoustic wave device having the resonance characteristics illustrated in FIG. 15 except that d/p was changed. FIG. 16 is a diagram illustrating a relationship between d/p and the fractional bandwidth as a resonator of the acoustic wave device.

As is clear from FIG. 16, when d/p>about 0.5, the fractional bandwidth is less than about 5% even when d/p is adjusted, for example. On the other hand, in the case of d/p about 0.5, for example, by changing d/p within the range, the fractional bandwidth can be set to equal to or more than about 5%, that is, a resonator having a high coupling coefficient can be provided. Further, when d/p is equal to or less than about 0.24, for example, the fractional bandwidth can be increased to equal to or more than about 7%, for example. In addition, when d/p is adjusted within this range, a resonator having a wider fractional bandwidth can be obtained, and a resonator having a higher coupling coefficient can be achieved. Therefore, it is understood that by setting d/p to equal to or less than about 0.5, for example, a resonator having a high coupling coefficient using the bulk waves in the above thickness shear mode can be provided.

FIG. 17 is a plan view of an acoustic wave device using bulk waves in the thickness shear mode. In an acoustic wave device 80, a pair of electrodes including the electrodes 3 and 4 are provided on the first main surface 2a of the piezoelectric layer 2. K in FIG. 17 is an intersecting width. As described above, in the acoustic wave devices according to preferred embodiments of the present invention, the number of pairs of electrodes may be one. Also in this case, when the above d/p is equal to or less than about 0.5, for example, the bulk waves in the thickness shear mode can be effectively excited.

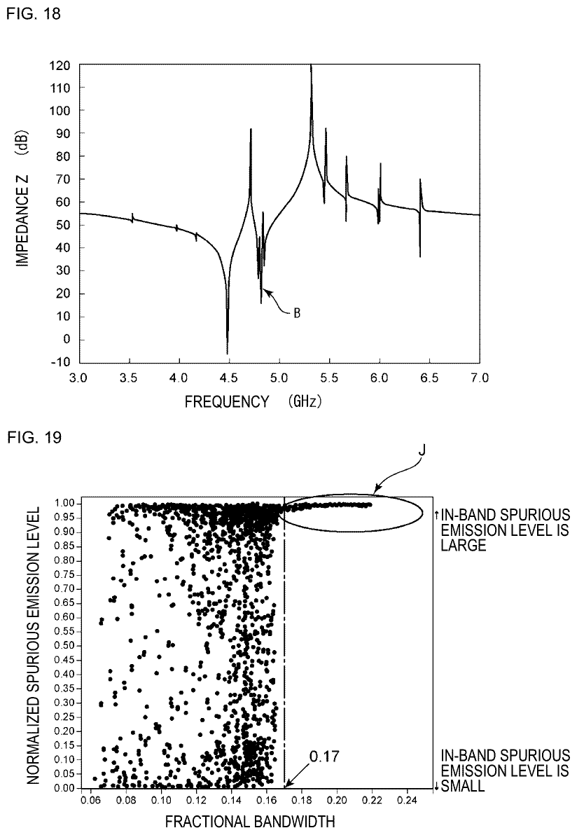

In the acoustic wave device 1, preferably, when viewed in a direction in which any adjacent electrodes 3 and 4 face each other, it is preferable that a metallization ratio MR of the above adjacent electrodes 3 and 4 with respect to the excitation region C, which is an overlapping region in the plurality of electrodes 3 and 4, satisfy MR about 1.75 (d/p)+0.075. In this case, a spurious emission can be effectively reduced. This will be described with reference to FIG. 18 and FIG. 19. FIG. 18 is a reference diagram illustrating an example of resonance characteristics of the above acoustic wave device 1. A spurious emission indicated by an arrow B appears between the resonant frequency and the anti-resonant frequency. Note that d/p=about 0.08 was set and the Euler angles of LiNbO₃ were (0°, 0°, 90°), for example. In addition, the above metallization ratio MR was set to about 0.35, for example.

The metallization ratio MR will be explained with reference to FIG. 11B. When attention is directed to a pair of electrodes 3 and 4 in the electrode structure of FIG. 11B, it is assumed that only the one pair of electrodes 3 and 4 is provided. In this case, a portion surrounded by an alternate long and short dash line is the excitation region C. The excitation region C is a region overlapping the electrode 4 in the electrode 3, a region overlapping the electrode 3 in the electrode 4, and a region in which the electrode 3 and the electrode 4 overlap each other in a region between the electrode 3 and the electrode 4, when the electrode 3 and the electrode 4 are viewed in a direction orthogonal or substantially orthogonal to the length direction of the electrodes 3 and 4, that is, in the facing direction. The area of the electrodes 3 and 4 in the excitation region C with respect to the area of the excitation region C is the metallization ratio MR. That is, the metallization ratio MR is the ratio of the area of the metallization portion with respect to the area of the excitation region C.

When a plurality of pairs of electrodes are provided, the ratio of the metallization portion included in the entire excitation region with respect to the sum of the areas of the excitation regions may be defined as MR.

FIG. 19 is a diagram illustrating a relationship between the fractional bandwidth and the phase rotation amount of the impedance of the spurious emission normalized by about 180 degrees as the magnitude of the spurious emission when a large number of acoustic wave resonators are configured according to the present preferred embodiment. The fractional bandwidth was adjusted by variously changing the film thickness of the piezoelectric layer and the dimension of the electrode. In addition, although FIG. 19 shows the result in the case of using the piezoelectric layer made of the Z-cut LiNbO₃, the same or substantially the same tendency is obtained even in the case of using the piezoelectric layer having another cut angle.

In a region surrounded by an ellipse J in FIG. 19, the spurious emission level is as large as about 1.0, for example. As is clear from FIG. 19, when the fractional bandwidth exceeds about 0.17, that is, when the fractional bandwidth exceeds about 17%, for example, a large spurious emission having the spurious emission level of 1 or more appears in the pass band even when the parameters configuring the fractional bandwidth are changed. That is, as in the resonance characteristics illustrated in FIG. 18, the large spurious emission indicated by an arrow B appears in the band. Therefore, the fractional bandwidth is preferably, for example, equal to or less than about 17%, for example. In this case, the spurious emission can be reduced by adjusting the film thickness of the piezoelectric layer 2, the dimensions of the electrodes 3 and 4, and the like.

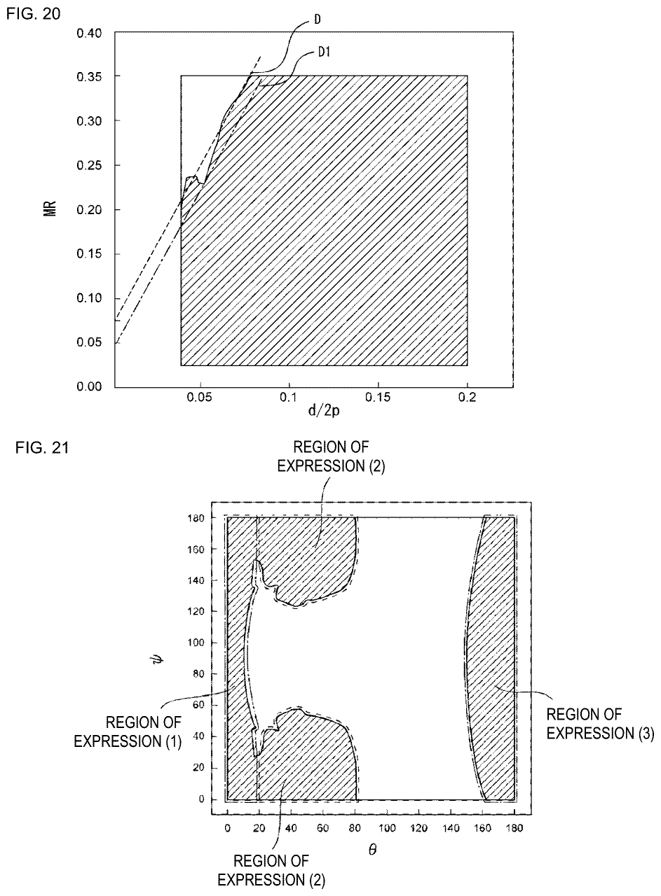

FIG. 20 is a diagram illustrating a relationship between d/2p, the metallization ratio MR, and the fractional bandwidth. In the above acoustic wave device, various acoustic wave devices having different d/2p and different MRs were formed, and the fractional bandwidth was measured. A hatched portion on the right side of a broken line D in FIG. 20 is a region in which the fractional bandwidth is equal to or less than about 17%, for example. A boundary between the hatched region and a non-hatched region is expressed by MR=about 3.5 (d/2p)+0.075, for example. That is, MR=about 1.75 (d/p)+0.075 is satisfied, for example. Therefore, MR about 1.75 (d/p)+0.075 is preferably satisfied, for example. In this case, the fractional bandwidth is likely to be equal to or less than about 17%, for example. More preferably, it is the region on the right side of MR=about 3.5 (d/2p)+0.05 indicated by an alternate long and short dash line D1 in FIG. 20, for example. That is, when MR about 1.75 (d/p)+0.05 is satisfied, the fractional bandwidth can be reliably set to equal to or less than about 17%, for example.

FIG. 21 is a diagram illustrating a map of the fractional bandwidth with respect to the Euler angles (0°, 0, $) of LiNbO₃ when d/p is made as close to 0 as possible. A hatched portion in FIG. 21 is a region in which the fractional bandwidth of at least equal to or more than about 5% is obtained, for example, and when the range of the region is approximated, the range is represented by the following Expression (1), Expression (2), and Expression (3).

(0°±10°,0° to 20°, arbitrary ψ) Expression (1)

(0°±10°,20° to 80°,0° to 60°(1−(θ−50)²/900)^{1/2}) or(0°±10°,20° to 80°,[180°−60°(1−(θ−50)²/900)^{1/2}] to 180°) Expression (2)

(0°±10°,[180°−30°(1−(ψ−90)²/8100)^{1/2}] to 180°, arbitrary ψ) Expression (3)

Therefore, in the case of the Euler angle range of the above Expression (1), Expression (2) or Expression (3), the fractional bandwidth can be sufficiently widened, which is preferable. The same applies to the case where the piezoelectric layer 2 is a lithium tantalate layer.

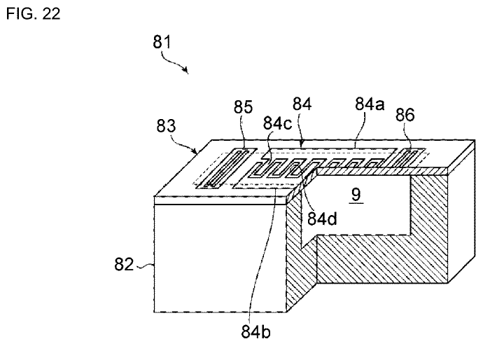

FIG. 22 is a partially cutaway perspective view illustrating an acoustic wave device using Lamb waves.

The acoustic wave device 81 includes a support substrate 82. The support substrate 82 includes a recess that is open to the upper surface. A piezoelectric layer 83 is stacked on the support substrate 82. Thus, the cavity portion 9 is provided. An IDT electrode 84 is provided on the piezoelectric layer 83 above the cavity portion 9. Reflectors 85 and 86 are provided on both sides of the IDT electrode 84 in an acoustic wave propagation direction. In FIG. 22, the outer peripheral edge of the cavity portion 9 is indicated by a broken line. Here, the IDT electrode 84 includes first and second busbars 84a and 84b, a plurality of first electrode fingers 84c, and a plurality of second electrode fingers 84d. The plurality of first electrode fingers 84c are connected to the first busbar 84a. The plurality of second electrode fingers 84d are connected to the second busbar 84b. The plurality of first electrode fingers 84c and the plurality of second electrode fingers 84d are interdigitated with each other.

In the acoustic wave device 81, Lamb waves as plate waves are excited by applying an alternating electric field to the IDT electrode 84 on the cavity portion 9. Since the reflectors 85 and 86 are provided on both sides, resonance characteristics by the above Lamb waves can be obtained.

As described above, the acoustic wave devices of preferred embodiments of the present invention may use plate waves. In this case, the IDT electrode 84, the reflector 85, and the reflector 86 illustrated in FIG. 22 may be provided on the piezoelectric layer in the first to fourth preferred embodiments or modifications thereof.

In the acoustic wave devices of the first to fourth preferred embodiments or modifications thereof including the acoustic wave resonator using bulk waves in the thickness shear mode, as described above, d/p is preferably, for example, equal to or less than about 0.5 and more preferably equal to or less than about 0.24, for example. As a result, even better resonance characteristics can be obtained. Furthermore, in the acoustic wave devices of the first to fourth preferred embodiments or the modification including the acoustic wave resonator using bulk waves in the thickness shear mode, MR about 1.75 (d/p)+0.075 is preferably satisfied as described above, for example. In this case, the spurious emission can be more reliably reduced or prevented.

The piezoelectric layer in the acoustic wave devices of the first to fourth preferred embodiments or modifications including the acoustic wave resonator using bulk waves in the thickness shear mode is preferably, for example, a lithium niobate layer or a lithium tantalate layer. Preferably, the Euler angles (φ, θ, ψ) of lithium niobate or lithium tantalate configuring the piezoelectric layer are in the range of the above Expression (1), Expression (2) or Expression (3). In this case, the fractional bandwidth can be sufficiently widened.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a support including a support substrate and a piezoelectric layer on the support and including a first main surface and a second main surface facing each other;
at least one functional electrode on the first main surface or the second main surface of the piezoelectric layer and including at least one pair of electrodes;
a first support on the piezoelectric substrate and surrounding the functional electrode;
at least one second support on the piezoelectric substrate and located in a portion surrounded by the first support; and
a lid portion on the first support and the at least one second support; wherein
a direction in which adjacent electrodes of the at least one pair of electrodes face each other is referred to as an electrode facing direction, a region in which the adjacent electrodes overlap each other when viewed from the electrode facing direction is an intersecting region, and a direction in which the at least one pair of electrodes extend is referred to as an electrode extending direction; and
the at least one second support does not overlap the intersecting region both when viewed from the electrode extending direction and when viewed from the electrode facing direction.

2. The acoustic wave device according to claim 1, wherein
a plurality of the functional electrodes are provided;
a plurality of resonators each including at least one of the functional electrodes are provided; and
the at least one second support is provided between two of the resonators.

3. The acoustic wave device according to claim 2, wherein
the plurality of resonators include a plurality of divided resonators; and
the at least one second support is provided between two of the divided resonators.

4. The acoustic wave device according to claim 1, wherein
a plurality of the functional electrodes are provided;
a plurality of resonators each including at least one of the functional electrodes are provided; and
the at least one second support is provided on the piezoelectric substrate at a location other than a portion between the two resonators.

5. The acoustic wave device according to claim 1, wherein the at least one second support is electrically connected to the at least one functional electrode.

6. The acoustic wave device according to claim 1, wherein
a plurality of the functional electrodes and a plurality of second supports are provided;
a plurality of resonators each including at least one of the functional electrode are provided; and
at least one pair of the plurality of second supports sandwich one of the resonators.

7. The acoustic wave device according to claim 6, wherein
the plurality of resonators include at least one series arm resonator and at least one parallel arm resonator; and
at least one pair of the plurality of second supports sandwich the at least one series arm resonator.

8. The acoustic wave device according to claim 6, wherein
the plurality of resonators include at least one series arm resonator and at least one parallel arm resonator; and
at least one pair of the plurality of second supports sandwich the at least one parallel arm resonator.

9. The acoustic wave device according to claim 6, wherein at least one pair of the plurality of second supports sandwich the resonator closest to an input end to which a signal is input.

10. The acoustic wave device according to claim 6, wherein, when an axis passing through a center of the intersecting region of at least one of the plurality of resonator in the electrode facing direction and extending in a direction orthogonal or substantially orthogonal to the electrode facing direction is referred to as a symmetry axis, the at least one pair of second supports sandwiching the one of resonators are not line-symmetric.

11. The acoustic wave device according to claim 1, wherein
at least one first cavity portion is provided in the support, and the first cavity portion overlaps at least a portion of the at least one functional electrode in plan view;
a second cavity portion surrounded by the piezoelectric substrate, the first support, and the lid portion is provided; and
when a dimension along a direction in which the piezoelectric substrate, the first support, and the lid portion are stacked is referred to as a height, a height of the first cavity portion is higher than a height of the second cavity portion.

12. The acoustic wave device according to claim 1, wherein
at least one first cavity portion is provided in the support, and the first cavity portion overlaps at least a portion of the at least one functional electrode in plan view;
a second cavity portion surrounded by the piezoelectric substrate, the first support, and the lid portion is provided; and
when a dimension along a direction in which the piezoelectric substrate, the first support, and the lid portion are stacked is referred to as a height, a height of the second cavity portion is higher than a height of the first cavity portion.

13. The acoustic wave device according to claim 1, wherein the support includes an intermediate layer between the support substrate and the piezoelectric layer.

14. The acoustic wave device according to claim 11, wherein the support includes an intermediate layer between the support substrate and the piezoelectric layer, and at least a portion of the first cavity portion is provided in the intermediate layer.

15. The acoustic wave device according to claim 1, wherein the lid portion includes a lid body including a semiconductor as a main component.

16. The acoustic wave device according to claim 1, wherein the piezoelectric layer is a lithium tantalate layer or a lithium niobate layer.

17. The acoustic wave device according to claim 1, wherein the at least one functional electrode includes first and second busbars facing each other, one or more first electrode fingers connected to the first busbar, and one or more second electrode fingers connected to the second busbar and facing the first electrode fingers.

18. The acoustic wave device according to claim 17, wherein the at least one functional electrode is an IDT electrode including the plurality of first electrode fingers and the plurality of second electrode fingers.

19. The acoustic wave device according to claim 18, wherein the acoustic wave device is structured to generate plate waves.

20. The acoustic wave device according to claim 17, wherein the acoustic wave device is structured to generate bulk waves in a thickness shear mode.

21. The acoustic wave device according to claim 17, wherein, when a thickness of the piezoelectric layer is defined as d, and a center-to-center distance between the first electrode finger and the second electrode finger adjacent to each other is defined as p, d/p is equal to or less than about 0.5.

22. The acoustic wave device according to claim 21, wherein d/p is equal to or less than about 0.24.

23. The acoustic wave device according to claim 20, wherein,
when viewed from the electrode facing direction, a region in which the first electrode finger and the second electrode finger adjacent to each other overlap each other is an excitation region; and
a metallization ratio of the one or more first electrode fingers and the one or more second electrode fingers with respect to the excitation region is defined as MR, MR about 1.75 (d/p)+0.075 is satisfied.

24. The acoustic wave device according to claim 20, wherein
the piezoelectric layer is a lithium tantalate layer or a lithium niobate layer; and
Euler angles (φ, θ, ψ) of lithium niobate or lithium tantalate forming the piezoelectric layer are in a range of the following Expression (1), Expression (2), or Expression (3):
(0°±10°,0° to 20°, arbitrary ψ) Expression (1)
(0°±10°,20° to 80°,0° to 60°(1−(θ−50)²/900)^{1/2}) or(0°±10°,20° to 80°,[180°−60°(1−(θ−50)²/900)^{1/2}] to 180°) Expression (2)
(0°±10°,[180°−30°(1−(ψ−90)²/8100)^{1/2}] to 180°, arbitrary ψ) Expression (3)
